(19) United States
(12) Patent Application Publication
(10) Pub. No.: US 2026/0020316 A1
(43) Pub. Date: Jan. 15, 2026

(54) Semiconductor Die Having a Field Oxide Thickness Transition Region and Method of Producing the Semiconductor Die

(71) Applicant: Infineon Technologies Dresden GmbH & Co. KG, Dresden (DE)

(72) Inventors: Cornelius Fuchs, Weinbohla (DE); Tom Schröder, Dresden (DE); Rolf Weis, Dresden (DE)

(21) Appl. No.: 18/770,818

(22) Filed: Jul. 12, 2024

(51) Int. Cl. H01L 29/423; H01L 23/64; H01L 27/088; H01L 29/06; H01L 29/51; H01L 29/66; H01L 29/78

(52) U.S. Cl. CPC H10D 64/516; H01L 23/647; H10D 30/0281; H10D 30/65; H10D 62/102; H10D 64/691; H10D 84/83

(57) ABSTRACT

A method includes: forming a first oxide layer having a thickness of 400 nm or less on a first main surface of a semiconductor wafer; forming a second layer on the first oxide layer; altering an etch rate of at least a first part of the second layer such that a horizontal component (r1) of the etch rate is greater than a vertical component (r2) of an etch rate of the first oxide layer; etching the oxide layers through an opening in a mask using an isotropic etchant, wherein due to the difference between r1 and r2, a first thickness transition region of the first oxide layer under the mask is etched with a taper of less than 45 degrees relative to the first main surface; after the etching, removing the second layer and then forming a gate oxide adjacent to the first thickness transition region.

### BACKGROUND

Lateral power semiconductor devices, particularly lateral high voltage devices, face a trade-off between device performance (e.g., low drain-to-source on resistance, high breakdown voltage, etc.) and reliability (e.g., hot carrier stress induced degradation, hot carrier induced drain breakdown, etc.). Enabling high device performance with high device reliability requires optimization of the electrical field distribution with respect to the geometrical shape of the device, particularly the field oxide shape, to avoid electric field spikes within the device.

Thus, there is a need for a lateral power semiconductor device design that optimizes the tradeoff between device performance with high device reliability.

### SUMMARY

According to an embodiment of a method, the method comprises: forming a first oxide layer on a first main surface of a semiconductor wafer, the first oxide layer having a thickness of 400 nm or less; forming a second layer on the first oxide layer; altering an etch rate of at least a first part of the second layer such that a horizontal component (r1) of the etch rate is greater than a vertical component (r2) of an etch rate of the first oxide layer; etching the second layer and the first oxide layer through an opening in a mask using an isotropic etchant, wherein due to the difference between r1 and r2, a first thickness transition region of the first oxide layer under the mask is etched with a taper of less than 45 degrees relative to the first main surface of the semiconductor wafer; after the etching, removing the second layer.

According to an embodiment of a semiconductor die, the semiconductor die comprises: a semiconductor substrate; a first lateral transistor device and a second lateral transistor device both formed in the semiconductor substrate and both comprising: a channel region; a gate electrode above the channel region and separated from a first main surface of the semiconductor substrate by a gate oxide; and a field oxide formed on the first main surface of the semiconductor substrate and onto which an extension of the gate electrode extends, wherein for the first lateral transistor device, the field oxide comprises a thickness transition region adjoining the gate oxide and having a taper of less than 45 degrees relative to the first main surface of the semiconductor substrate, wherein for the second lateral transistor device, the field oxide comprises a thickness transition region adjoining the gate oxide and having a taper of approximately 45 degrees relative to the first main surface of the semiconductor substrate.

According to another embodiment of a semiconductor die, the semiconductor die comprises: a semiconductor substrate; a source region of a first conductivity type formed in a first main surface of the semiconductor substrate; a drift region of the first conductivity type formed in the first main surface of the semiconductor substrate; a channel region of a second conductivity type opposite the first conductivity type formed in the first main surface of the semiconductor substrate and separating the source region and the drift region; a drain region of the first conductivity type formed in the first main surface of the semiconductor substrate and separated from the channel region by the drift region; a gate electrode above the channel region and separated from the first main surface of the semiconductor substrate by a gate oxide; and a field oxide formed on the first main surface of the semiconductor substrate and onto which an extension of the gate electrode extends, wherein the field oxide comprises a thickness transition region adjoining the gate oxide and having a taper of less than 45 degrees relative to the first main surface of the semiconductor substrate, wherein the extension of the gate electrode extends onto the thickness transition region of the field oxide with the same taper as the thickness transition region.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a top plan view of a semiconductor wafer and an enlarged cross-sectional view of part of a lateral power transistor device integrated in a die of the semiconductor wafer and having field oxide thickness transition region adjacent to a gate oxide of the lateral power transistor device.

FIGS. 2A through 2D illustrate cross-sectional views at different stages of producing the field oxide thickness transition region adjacent to the gate oxide of the lateral power transistor device.

FIG. 3 illustrates a top plan view of the semiconductor wafer and an enlarged cross-sectional view of part of two lateral power transistor devices integrated in a die of the semiconductor wafer and each having a field oxide thickness transition region adjacent to a gate oxide but with different tapers.

FIGS. 4A through 4F illustrate cross-sectional views at different stages of producing field oxide thickness transition regions with different taper angles in the same semiconductor wafer or integrated in the same semiconductor die.

### DETAILED DESCRIPTION

The embodiments described herein provide a method which enables implementation of a field oxide having a taper less than 45 degrees next to the gate structure of a lateral power transistor device. A lateral power transistor device with such a shallow tapered field oxide formed next to the gate structure may be integrated alongside other lateral power transistor devices having a field oxide with a steeper taper angle, e.g., approximately 45 degrees. A field oxide taper of less 45 degrees next to the gate structure may be achieved by modifying the etch rate of a sacrificial oxide on top of a field oxide using a damaging implant. To achieve two different taper angles, the total dose of the implant may be split where one is masked by a lithography mask. The shallow tapered field oxide improves the electrical field distribution around the gate structure compared to a standard thick field oxide geometry having a steeper taper angle, increasing the figure of merit for performance parameters such as Rds(on) (drain-to-source on resistance), breakdown voltage, etc. while enabling device reliability requirements such as hot carrier stress induced degradation, hot carrier induced drain breakdown, etc.

Described next with reference to the figures are embodiments of producing the shallow tapered field oxide and semiconductor devices that utilize the shallow tapered field oxide.

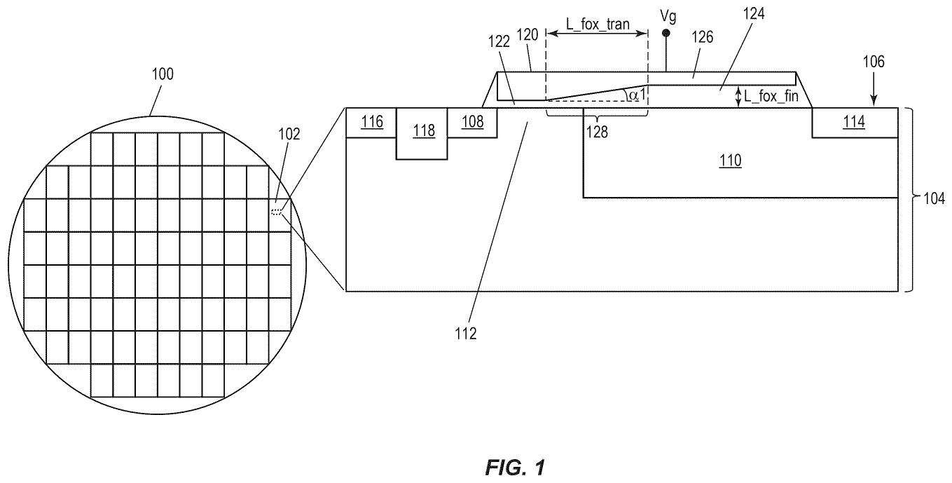

FIG. 1 illustrates a top plan view of a semiconductor wafer 100 and an enlarged cross-sectional view of part of a lateral power transistor device integrated in a die (chip) 102 of the semiconductor wafer 100. The lateral power transistor device may be integrated in some or all of the semiconductor dies 102, and the semiconductor dies 102 may or may not be singulated yet in the top plan view of FIG. 1.

Each semiconductor die 102 includes a semiconductor substrate 104. The semiconductor substrate 104 comprises one or more semiconductor materials that are used to form the lateral power transistor device. For example, the semiconductor substrate 104 may comprise Si, silicon carbide (SiC), germanium (Ge), silicon germanium (SiGe), gallium nitride (GaN), gallium arsenide (GaAs), and the like. The semiconductor substrate 104 may include one or more epitaxial layers where one or more regions of the lateral power transistor device are formed.

The power transistor device shown in the enlarged view of FIG. 1 is a lateral device in that the primary (load) current pathway of the device is along the front main surface 106 of the semiconductor substrate 104. More particularly, the lateral power transistor device includes a source region 108 of a first conductivity type formed in the front main surface 106 of the semiconductor substrate 104 and a drift region 110 of the first conductivity type formed in the front main surface 106 of the semiconductor substrate 104. A channel (body) region 112 of a second conductivity type opposite the first conductivity type is formed in the front main surface 106 of the semiconductor substrate 104 and separates the source region 108 and the drift region 110 from one another. A drain region 114 of the first conductivity type is formed in the front main surface 106 of the semiconductor substrate 104 and separated from the channel region 112 by the drift region 110.

The lateral power transistor device may also include a body contact region 116 of the second conductivity type. The body contact region 116 has a higher doping concentration than the channel region 112, to provide an ohmic connection with a source metallization (not shown) formed above the semiconductor substrate 104. An insulation structure 118 such as STI (shallow trench isolation) may be formed in the front main surface 106 of the semiconductor substrate 104 between the body contact region 116 and the source region 108.

The first conductivity can be p-type and the second conductivity type can be n-type, or the first conductivity can be n-type and the second conductivity type can be p-type. The lateral power transistor device can be an enhancement-mode device or a depletion-mode device. In either case, the main current pathway is between the source region 108 and the drain region 114 along the front main surface 106 of the semiconductor substrate 104 and controlled by the conductive state of the channel region 112.

The conductive state of the channel region 112 is controlled by a voltage Vg applied to a gate electrode 120 formed above the channel region 112 and separated from the front main surface 106 of the semiconductor substrate 104 by a gate oxide 122. For a normally-off (i.e., enhancement node) device, the channel region 112 is off at zero gate-source voltage. The device can be turned on by pulling the gate voltage Vg higher (for an NMOS device) or lower (for a PMOS device) than the source voltage. A field oxide 124 is formed on the front main surface 106 of the semiconductor substrate 104 and adjoins the gate oxide 122. The gate electrode 120 extends onto the field oxide 124 to form a field plate extension 126 in the direction of the drain region 114. The field plate extension 126 helps shield the gate oxide 122 from excessive electric fields at the drain-side of the gate structure.

The field oxide 124 includes a thickness transition region 128 that adjoins the gate oxide 122 at the drain-side of the gate structure. The thickness of the field oxide 124 gradually increases along the thickness transition region 128 in the direction of the drain region 114. Accordingly, the thickness transition region 128 of the field oxide 124 has a taper instead of a stepwise transition in thickness or a uniform thickness. The taper is represented by angle α1 in the enlarged view of FIG. 1 and is less than 45 degrees relative to the front main surface 106 of the semiconductor substrate 104. The field plate extension 126 of the gate electrode 120 extends onto the thickness transition region 128 of the field oxide 124 and has the same taper (α1) as the thickness transition region 128 of the field oxide 124. In one embodiment, the field oxide 128 has a final thickness L_fox_fin in a range of 20 nm to 400 nm below the extension 126 of the gate electrode 120 outside the thickness transition region 128.

A high electric field typically arises at the Si—SiO₂ interface at the drain-side edge of the gate electrode structure of lateral power transistor devices. If the electric field becomes too high, hot carrier injection (HCl) occurs which can lead to hot carrier stress (HCS) induced degradation of the device. A taper of 45 degrees for a field oxide at the drain-side of a gate structure was observed to result in enhanced HCl which contributes to the creation of trap states in the Si—SiO₂ interface, causing device parameter shifts over the device lifetime.

By reducing the taper of the field oxide thickness transition region 128 to an angle α1 less than 45 degrees as shown in FIG. 1, e.g., α1 in a range of 5° to 15°, the length L_fox_tran of the field oxide thickness transition region 128 increases in the direction of the drain region 114 as compared to a larger taper angle, e.g., 45°. In one embodiment, the field oxide 124 has a thickness T_fox_fin in a range of 20 nm to 400 nm below the extension 126 of the gate electrode 120 outside the thickness transition region 128 of the field oxide 124.

The increase in length ΔL_fox_tran of the field oxide thickness transition region 128 that results from decreasing the taper angle α1 below 45° reduces the peak electric field strength at the drain-side edge of the gate structure and at the beginning of the transition region 128. A lower electric field in this region of the device strongly reduces impact ionization just below the front main surface 106 of the semiconductor substrate 104, which is critical for reducing HCl-related device degradation. The trade-off between lower Rds(on) and both higher breakdown voltage and increased device stability can be better optimized by tapering the field oxide thickness transition region 128 at an angle less than 45 degrees. This means that the lateral power transistor device may have a breakdown voltage of 20V, 40V, 65V or even higher and sufficient device stability with increased Rds(on)*A compared to devices with taper angles >=45°, where A represents area of the semiconductor die 102 that includes the lateral power transistor device.

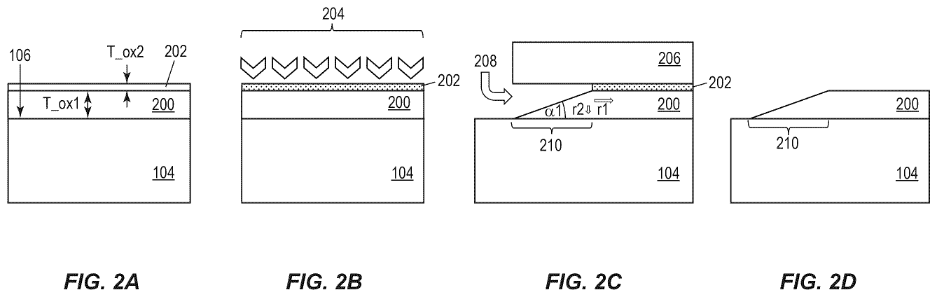

FIGS. 2A through 2D illustrate cross-sectional views at different stages of producing the field oxide thickness transition region 128 adjacent to the gate oxide 122 of the lateral power transistor device. The cross-sectional views correspond to the part of the lateral power transistor device shown in the enlarged view of FIG. 1.

FIG. 2A shows the semiconductor substrate 104 after a first oxide layer 200 is formed on the front main surface 106 of the semiconductor wafer 104 and a second layer 202 is formed on the first oxide layer 200. In one embodiment, the first oxide layer 200 has a thickness T_ox1 of 400 nm or less.

The first oxide layer 200 may be formed using a thick gate oxide deposition process, e.g., using a CVD (chemical vapor deposition) gate oxide deposition process. The composition of the second layer 202 may be selected as desired, so long as the material of the second layer 202 etches at a faster rate compared to the first oxide layer 200. For example, the second layer 202 may comprise a material which can be monocrystalline, where the etching of the first oxide layer 200 is isotropic but not for the second layer 202, i.e. the first oxide layer 200 has a higher etch rate in the horizontal direction and a lower or comparable etch rate to the second layer 200 in the vertical direction.

In one embodiment, the second layer 202 as deposited etches faster compared to the first oxide layer 200. In another embodiment, the second layer 202 etches faster compared to the first oxide layer 200 after being damaged by an implant. In another embodiment, the second layer 202 etches faster compared to the first oxide layer 200 after an additional anneal. In another embodiment, the second layer 202 etches faster compared to the first oxide layer 200 after being damaged by an implant and after an additional anneal.

The material of the second layer 202 can be an oxide, a nitride, or any other material which can be etched away faster than the material of the first oxide layer 200, e.g., by being damaged by an implantation process. In the case of oxide as the second layer 202, the second layer 202 may be formed by oxide deposition on the first oxide layer 200, e.g., by CVD of a silane-based (SiH₄) oxide. The thickness T_ox2 of the second layer 202 may be less than the thickness T_ox1 of the first oxide layer 200. For example, T_ox2 may be approximately 20 nm.

FIG. 2B shows the semiconductor substrate 104 during altering of the etch rate of at least a first part of the second layer 202 such that a horizontal component (r1) of the etch rate is greater than a vertical component (r2) of the etch rate of the first oxide layer 200, where etch rate is the rate at which a material is etched. In one embodiment, r1/r2 is in a range of 3 to 4.

Altering the etch rate of at least the first part of the second layer 202 enables subsequent forming of a lower taper angle α1 for the field oxide thickness transition region 128. In FIG. 2B, the etch rate of at least the first part of the second layer 202 is altered by implanting an atomic species 204 into at least the first part of the second layer 202 at an energy and a dose that limit the implant depth of the atomic species 204 to the second layer 202. That is, the energy and the dose of the implanted atomic species 204 are chosen so that the overwhelming majority (95% or more) of the implanted atomic species 204 settles in the second layer 202 and does not reach the first oxide layer 200, e.g., in the case of oxide as the material of the second layer 202.

In one embodiment, the atomic species 204 is arsenic. For arsenic as the atomic species 204 and T_ox2 of approximately 20 nm, the implantation energy may be in a range of 1 to 10 keV and the implantation dose may be in a range of 1E13 to 1E16 atoms/cm².

The atomic species 204 implanted into the second layer 202 damages the second layer 202, changing the etch rate of the second layer 202. This way, the second layer 202 can be etched at a faster rate in the horizontal direction than the underlying first oxide layer 200 etches in the vertical direction.

FIG. 2C shows the semiconductor substrate 104 during etching of the second layer 202 and the first oxide layer 200 through an opening in a mask 206 such as a resist mask, using an isotropic etchant 208. In one embodiment, the isotropic etchant 208 is a wet etchant such as hydrofluoric acid or buffered (e.g., ammonia fluoride) hydrofluoric acid. More generally, the etching is isotropic, i.e., the same in the vertical and horizontal directions. However, since the etch rate of at least the first part of the second layer 202 was previously altered such that the horizontal component r1 of the etch rate of the second layer 202 is greater than the vertical component r2 of the etch rate of the first oxide layer 200, the second layer 202 etches faster in the horizontal direction than the first oxide layer 200 etches in the vertical direction. For example, if b=r1/r2 equals one (1), the resulting taper angle α1 of the field oxide thickness transition region 128 will be approximately 45 degrees. However, if r1>r2 (e.g., r1/2 is in a range of 3 to 4), b>1 and the taper angle α1 of the field oxide thickness transition region 128 will be less than 45 degrees. In one embodiment, b is selected such that α1 is in a range of 5° to 15°.

During the etching of the second layer 202 and the first oxide layer 200 using the isotropic etchant 208, a first thickness transition region 210 of the first oxide layer 200 under the mask 206 is etched with a taper α1 of less than 45 degrees relative to the first main surface 106 of the semiconductor wafer 104 due to the difference between r1 and r2. The first thickness transition region 210 of the first oxide layer 200 shown in FIG. 2C corresponds to the field oxide thickness transition region 128 of the lateral power transistor device shown in FIG. 1.

FIG. 2D shows the semiconductor substrate 104 after the etching is complete and the mask 206 and the second layer 202 are removed. Hence, the second layer 202 is used as a sacrificial layer. The second layer 202 is doped in this embodiment to enable the etch rate difference r1>r2 and therefore is removed before forming the gate oxide 122 of the lateral power transistor device, so that the atomic species 204 previously implanted into the second layer 202 do not diffuse into the gate oxide 122. The gate oxide 122 is formed on the front main surface 106 of the semiconductor substrate 104 adjacent to the field oxide thickness transition region 128 and is not shown in FIG. 2D. Any gate oxidation process suitable for lateral power transistor devices may be used to form the gate oxide 122, e.g., such as thermal oxidation and annealing. In another embodiment, the second layer 202 is not sacrificial but remains part of the final device.

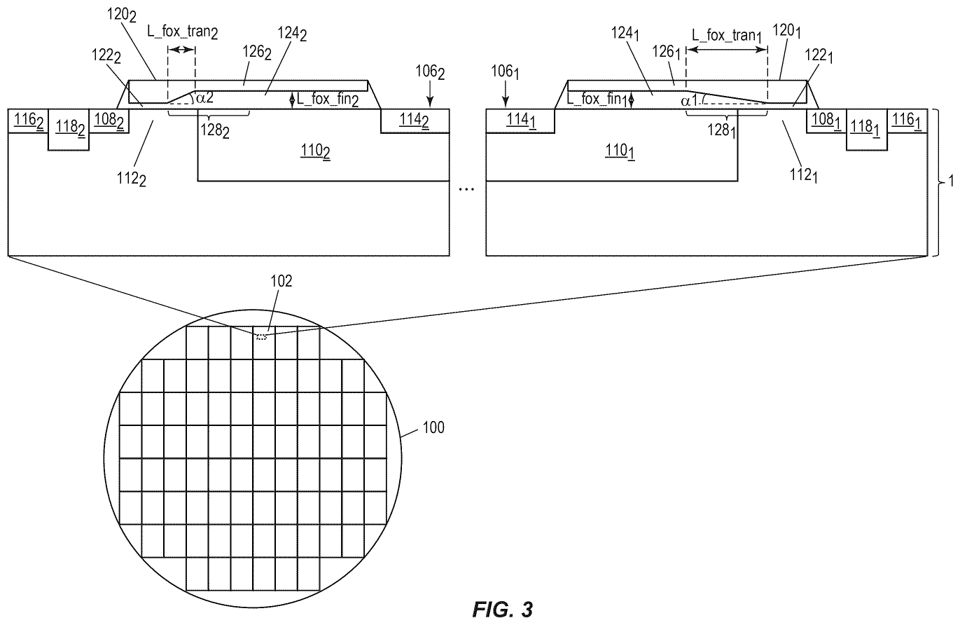

FIG. 3 illustrates a top plan view of the semiconductor wafer 100, according to another embodiment. In this embodiment, one or more of the semiconductor dies 102 includes the lateral power transistor device having the field oxide thickness transition region 128 with a taper angle α1 less than 45 degrees relative to the first main surface 106 of the semiconductor substrate 104 and a second lateral power transistor device integrated in the same substrate 104. The first and second lateral power transistor devices have the same device regions in the enlarged view of FIG. 3, with subscript ‘1’ indicating the device regions of the first lateral power transistor device with the shallow tapered field oxide thickness transition region 128 and subscript ‘2’ indicating the device regions of the second lateral power transistor device.

Like the first lateral power transistor device, the second lateral power transistor device also has a field oxide 124₂ that includes a thickness transition region 128₂ that adjoins the gate oxide 122₂ at the drain-side of the gate structure. The first and second lateral power transistor devices may be integrated in the same die 102 as shown in the enlarged view of FIG. 3, or at least in the same wafer 100 but in different dies 102. In one embodiment, for both the first lateral transistor device and the second lateral transistor device, the field oxide 128₁, 128₂ has a final thickness L_fox_fin1, L_fox_fin2 in a range of 20 nm to 400 nm below the extension 126₁, 126₂ of the gate electrode 120₁, 120₂ outside the respective thickness transition region 128₁, 128₂.

In FIG. 3, the field oxide thickness transition region 128₂ of the second lateral power transistor device has a taper angle α2>α1 relative to the first main surface 106 of the semiconductor substrate 104. For example, α2 may be approximately (e.g., +/−5%) 45 degrees relative to the first main surface 106 of the semiconductor substrate 104 and α1 may be in a range of 5° to 15°. FIG. 3 also includes an enlarged cross-sectional view of part of both lateral power transistor devices integrated in the same semiconductor die 102 of the semiconductor wafer 100.

Since α1<α2, the length L_fox_tran1 of the field oxide thickness transition region 128₁ of the first lateral power transistor device is greater than the length L_fox_tran2 of the field oxide thickness transition region 128₂ of the second lateral power transistor device. This means that the first lateral power transistor device has a lower peak electric field strength at the drain-side edge of the gate structure compared to the second lateral power transistor device. Accordingly, the first lateral power transistor device may have a better optimized trade-off between lower Rds(on) and both higher breakdown voltage and increased device stability as compared to the second lateral power transistor device.

In one embodiment, the first lateral power transistor device has a lower Rds(on)*A compared to the second lateral transistor device. Separately or in combination, the first lateral power transistor device may have a higher breakdown voltage compared to the second lateral power transistor device. For example, the first lateral power transistor device may have a breakdown voltage of 65V and the second lateral power transistor device may have a breakdown voltage of 20V. For some applications, it may be beneficial to produce legacy devices such as the second lateral power transistor device with the wider field oxide taper angle α2 on the same semiconductor die 102 or wafer 100 as the first lateral power transistor device with the shallower field oxide taper angle α1.

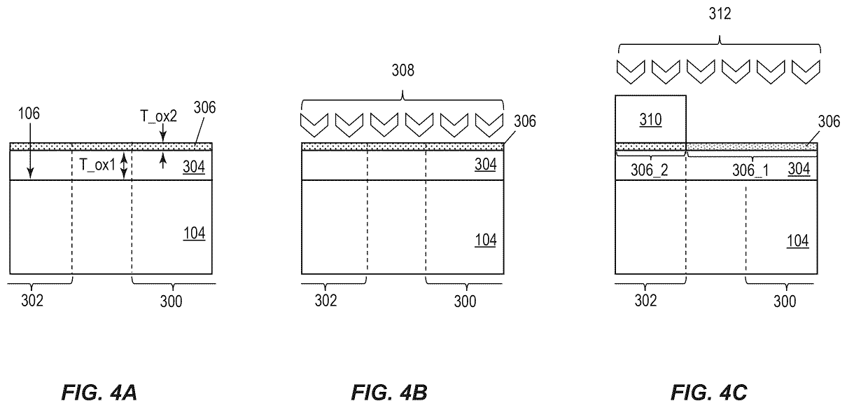

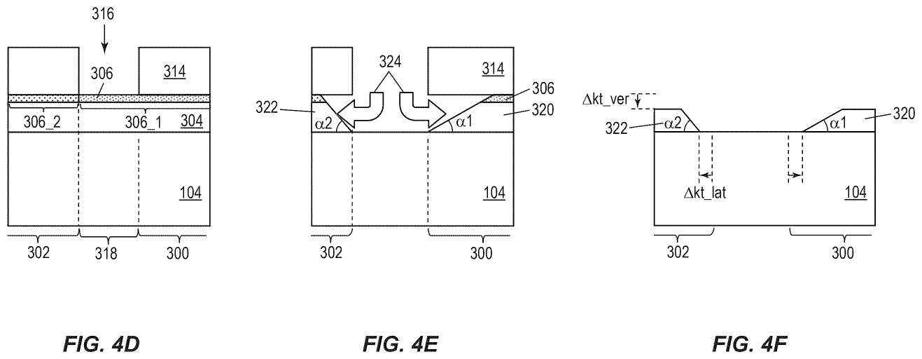

FIGS. 4A through 4F illustrate cross-sectional views at different stages of producing the field oxide thickness transition regions 128₁, 128₂ having different taper angles α1, α2 in the same semiconductor wafer 100 or even integrated in the same semiconductor die 102. The cross-sectional views correspond to the part of the first and second lateral power transistor devices shown in the enlarged view of FIG. 3.

According to the embodiment illustrated in FIGS. 4A through 4F, the second lateral power transistor device with the wider field oxide taper angle α2 is formed in the same semiconductor die 102 or wafer 100 as the first lateral power transistor device with the shallower field oxide taper angle α1. FIGS. 4A through 4F indicate the two (2) different device type regions 300, 302 of the semiconductor wafer 100 or die 102 using vertical dashed lines, where the field oxide thickness transition region 128₁ with the shallower field oxide taper angle α1 is formed in a first device type region 300 and the field oxide thickness transition region 128₂ with the wider field oxide taper angle α2 is formed in the second device type region 302 of the wafer 100 or die 102.

FIG. 4A shows the semiconductor substrate 104 after a first oxide layer 304 is formed on the front main surface 106 of the semiconductor substrate 104 and a second layer 306 is formed on the first oxide layer 304. In one embodiment, the first oxide layer 304 has a thickness T_ox1 of 400 nm or less.

The first oxide layer 304 may be formed using a thick gate oxide deposition process, e.g., using a CVD (chemical vapor deposition) gate oxide deposition process. The second layer 306 may be formed by oxide deposition on the first oxide layer 304, e.g., by CVD of a silane-based oxide. The thickness T_ox2 of the second layer 306 may be less than the thickness T_ox1 of the first oxide layer 304. For example, T_ox2 may be approximately 20 nm.

FIG. 4B shows the semiconductor substrate 104 during adjusting the etch rate of the second layer 306 such that the etch rate of the second layer 306 is closer to or matches the etch rate of the first oxide layer 304. The first implant is performed if the first oxide layer 304 and the second layer 306 do not have identical compositions, which is likely if the first oxide layer 304 and the second oxide layer 306 are formed using different processes, e.g., a CVD gate oxide deposition process for the first oxide layer 304 and by CVD of a silane-based oxide for the second layer 306. If the first oxide layer 304 and the second oxide layer 306 do not have identical compositions, then the first oxide layer 304 and the second oxide layer 306 will have different etch rates unless the etch rate of one of the first and second layers 304, 306 is altered.

In one embodiment, a blanket (uniform) implant of an atomic species 308 into the second layer 306 is performed to alter the etch rate of the entire second layer 306 such that the etch rate of the second layer 306 is closer to or matches the etch rate of the first oxide layer 304. In one embodiment, the first oxide layer 304 has a etch rate that yields a taper angle of 45 degrees when etched using a mask. The implant energy and dose of the first implant process illustrated in FIG. 4B may be chosen such that the second layer 306 also has a etch rate that yields a taper angle of 45 degrees when etched using the same mask.

FIG. 4C shows the semiconductor substrate 104 during altering of the etch rate of a first part 306_1 of the second layer 306 such that a horizontal component (r1) of the etch rate of the first part 306_1 of the second layer 306 is greater than a vertical component (r2) of the etch rate of the first oxide layer 304. In one embodiment, r1/r2 is in a range of 3 to 4.

Altering the etch rate of the first part 306_1 of the second layer 306 enables subsequent forming of a lower taper angle α1 for the field oxide thickness transition region 128₁ in the first device type region 300 of the semiconductor wafer 100 or die 102. The etch rate of the adjoining second part 306_2 of the second layer 306 remains unaltered by use of a mask 310 such as a lithography mask that shields the second part 306_2 of the second layer 306 in the second device type region 302 of the semiconductor wafer 100 or die 102.

In FIG. 4C, the etch rate of the first part 306_1 of the second layer 306 is altered by way of a second implant process. The second implant process includes implanting an atomic species 312 into the first (unmasked) part 306_1 of the second layer 306 at an energy and a dose that limit the penetration depth of the atomic species 312 to the second layer 306. In one embodiment, the atomic species 312 is arsenic. For arsenic as the atomic species 312 and T_ox2 of approximately 20 nm, the implantation energy may be in a range of 1 to 10 keV and the implantation dose may be in a range of 1E13 to 1E16 atoms/cm².

The second implant process damages the unmasked first part 306_1 of the second layer 306, changing the etch rate of the first part 306_1 of the second layer 306. This way, the first part 306_1 of the second layer 306 can be etched at a faster rate in the horizontal direction than the underlying first oxide layer 304 etches in the vertical direction (i.e., r1>r2 for the first part 306_1 of the second layer 306). The mask 310 shields the second part 306_2 of the second layer 306, such that the atomic species 312 is restricted to the first part 306_1 of the second layer 306. According to this embodiment, the second (masked) part 306_2 of the second layer 306 will etch at the same rate in the horizontal direction as the underlying first oxide layer 304 etches in the vertical direction (i.e., r1=r2 for the second part 306_2 of the second layer 306).

FIG. 4D shows the semiconductor substrate 104 after an etch mask 314 such as a lithography mask is formed on the second layer 306. The etch mask 314 has an opening 316 for introducing an etchant, which can be in one embodiment a wet etchant such as hydrofluoric acid or buffered (e.g., ammonia fluoride) hydrofluoric acid, to the second layer 306 in a region 318 of the semiconductor wafer 100 or die 102 that is interposed between the first device type region 300 and the second device type region 302.

FIG. 4E shows the semiconductor substrate 104 during etching of the second layer 306 through the opening 316 in the etch mask 314. The etching is isotropic, i.e., the same in the vertical and horizontal directions. However, since the etch rate of the first part 306_1 of the second layer 306 was previously altered such that the horizontal component r1 of the etch rate of the first part 306_1 of the second layer 306 is greater than the vertical component r2 of the etch rate of the first oxide layer 304, the first part 306_1 of the second layer 306 etches faster in the horizontal direction than the first oxide layer 304 etches in the vertical direction. Since the etch rate of the second part 306_2 of the second layer 306 was unaltered during the second implant process shown in FIG. 4C, r1=r2 for the second part 306_2 of the second layer 306.

Accordingly, b=r1/r2 equals one (1) for the second part 306_2 of the second layer 306 and the resulting taper angle α2 of the first oxide layer 304 in the second device type region 302 of the semiconductor wafer 100 or die 102 is approximately 45 degrees. Since r1>r2 (e.g., r1/2 is in a range of 3 to 4) for the first part 306_1 of the second layer 306, b>1 and the taper angle α1 of the first oxide layer 304 in the first device type region 300 of the semiconductor wafer 100 or die 102 is less than 45 degrees. In one embodiment, b is selected such that α1 is in a range of 5° to 15° in the first device type region 300 of the semiconductor wafer 100 or die 102.

At the start of the etching process, a first thickness transition region 320 of the first oxide layer 304 is covered by the first (altered) part 306_1 of the second layer 306 and a second thickness transition region 322 of the first oxide layer 304 is covered by the second (unaltered) part 306_2 of the second layer 306. During the etching of the second layer 306 and the first oxide layer 304 through the opening 316 in the mask 314 using an isotropic etchant 324, the first thickness transition region 320 of the first oxide layer 304 under the mask 314 is etched with a taper angle α1 of less than 45 degrees relative to the first main surface 106 of the semiconductor substrate 104 due to the difference between r1 and r2 in the first device type region 300. The second thickness transition region 322 of the first oxide layer 304 is etched under the mask 314 with a taper angle α2>α1, e.g., approximately 45 degrees, relative to the first main surface 106 of the semiconductor substrate 104 due to little or no difference between r1 and r2 in the second device type region 302.

The first thickness transition region 320 of the first oxide layer 304 with the taper angle α1 shown in FIG. 4E corresponds to the field oxide thickness transition region 128₁ of the first lateral power transistor device shown in FIG. 3. The second thickness transition region 322 of the first oxide layer 304 with the taper angle α2 shown in FIG. 4E corresponds to the field oxide thickness transition region 128₂ of the second lateral power transistor device shown in FIG. 3. Accordingly, the first thickness transition region 320 of the first oxide layer 304 is part of a first device type and the second thickness transition region 322 of the first oxide layer 304 is part of a second device type. The first device type may have a lower Rds(on)*A compared to the second device type. Separately or in combination, the first device type may have a higher breakdown voltage compared to the second device type.

FIG. 4F shows the semiconductor substrate 104 after removal of the etch mask 314 and the second (sacrificial) oxide layer 306. Removal of the second layer 306 may result in some lateral and/or vertical recessing of the first oxide layer 304. The amount of lateral recess Δkt_lat and the amount of vertical recess Δkt_ver are both indicated in FIG. 4F. In one embodiment, for both the first device type and the second device type, the field oxide 124₁, 124₂ formed by the first oxide layer 304 has a final thickness L_fox_fin1, L_fox_fin2 in a range of 20 nm to 400 nm below the extension 126₁, 126₂ of the gate electrode 120₁, 120₂ outside the respective thickness transition regions 128₁, 128₂, e.g., as shown in FIG. 3.

The gate structures of the different device types may be formed by forming a gate oxide 122₁, 122₂ on the exposed part of the front main surface 106 of the semiconductor substrate 104, e.g., by a CVD gate oxide deposition process. First and second gate electrodes 120₁, 120₂ are then formed on the gate oxide 122₁, 122₂, e.g. via polysilicon and/or metal deposition. The first gate electrode 122₁ is part of the first device type and has an extension 126₁ that extends onto the first thickness transition region 320 of the first oxide layer 304. The second gate electrode 122₂ is part of the second device type and has an extension 126₂ that extends onto the second thickness transition region 322 of the first oxide layer 304.

FIG. 3 shows the device regions 300, 302 after the gate electrodes 120₁, 120₂ are formed. Relative to the first main surface 106 of the semiconductor substrate 104, the extension 126₁ of the first gate electrode 120₁ is sloped at a smaller angle (α1) above the first field oxide thickness transition region 128₁ compared to the extension 126₂ of the second gate electrode 120₂ above the second field oxide thickness transition region 128₂ (i.e., α1<α2, as shown in FIG. 3). The different field oxide taper angles α1, α2 enables the first lateral power transistor device to have one or more different parameters such as lower Rdson, higher breakdown voltage, etc. compared to the second lateral power transistor device, without sacrificing device reliability requirements such as hot carrier stress induced degradation, hot carrier induced drain breakdown, etc.

The semiconductor wafer 100 is eventually singulated into a plurality of individual semiconductor dies 102, e.g., by sawing, laser cutting, electrical discharge machining, etc. Each of the individual semiconductor dies 102 may include a lateral power transistor of the first device type and a lateral transistor of the second device type shown in FIG. 3 and produced by the method illustrated in FIGS. 4A through 4F, including the differently tapered field oxide thickness transition regions 128₁, 128₂.

Although the present disclosure is not so limited, the following numbered examples demonstrate one or more aspects of the disclosure.

Example 1. A method, comprising: forming a first oxide layer on a first main surface of a semiconductor wafer, the first oxide layer having a thickness of 400 nm or less; forming a second layer on the first oxide layer; altering an etch rate of at least a first part of the second layer such that a horizontal component (r1) of the etch rate is greater than a vertical component (r2) of an etch rate of the first oxide layer; etching the second layer and the first oxide layer through an opening in a mask using an isotropic etchant, wherein due to the difference between r1 and r2, a first thickness transition region of the first oxide layer under the mask is etched with a taper of less than 45 degrees relative to the first main surface of the semiconductor wafer; after the etching, removing the second layer; and after removing the second layer, forming a gate oxide adjacent to the first thickness transition region.

Example 2. The method of example 1, wherein r1/r2 is in a range of 3 to 4.

Example 3. The method of example 1 or 2, wherein the taper is in a range of 5° to 15°.

Example 4. The method of any of examples 1 through 3, wherein altering the etch rate of at least the first part of the second layer comprises: implanting an atomic species into at least the first part of the second layer at an energy and a dose that limit the atomic species to the second layer.

Example 5. The method of example 4, wherein the atomic species is arsenic.

Example 6. The method of example 5, wherein the energy is in a range of 1 to 10 keV, and wherein the dose is in a range of 1E13 to 1E16 atoms/cm².

Example 7. The method of any of examples 4 through 6, further comprising: before both the altering and the etching, adjusting the etch rate of the second layer such that the etch rate of the second layer is closer to or matches the etch rate of the first oxide layer, wherein during the implanting of the atomic species, the mask shields a second part of the second layer laterally adjoining the first part of the second layer such that the atomic species is restricted to the first part of the second layer, wherein at the start of the etching, the first thickness transition region is covered by the first part of the second layer and a second thickness transition region of the first oxide layer under the mask is covered by the second part of the second layer, wherein during the etching, the second thickness transition region is etched with a taper of approximately 45 degrees relative to the first main surface of the semiconductor wafer.

Example 8. The method of example 7, wherein the first thickness transition region is part of a first device type, and wherein the second thickness transition region is part of a second device type.

Example 9. The method of example 8, further comprising: singulating the semiconductor wafer into a plurality of semiconductor dies, each of the semiconductor dies including the first device type and the second device type.

Example 10. The method of example 8 or 9, further comprising: forming a first gate electrode on the gate oxide, the first gate electrode being part of the first device type and having an extension that extends onto the first thickness transition region; and forming a second gate electrode on the gate oxide, the second gate electrode being part of the second device type and having an extension that extends onto the second thickness transition region, wherein relative to the first main surface of the semiconductor wafer, the extension of the first gate electrode is sloped at a smaller angle above the first thickness transition region compared to the extension of the second gate electrode above the second thickness transition region.

Example 11. The method of any of examples 8 through 10, wherein the first device type has a lower Rds(on)*A compared to the second device type, where Rds(on) is on resistance and A is die area for the device type.

Example 12. The method of any of examples 8 through 11, wherein the first device type has a higher breakdown voltage compared to the second device type.

Example 13. The method of any of examples 1 through 12, wherein the second layer is an oxide layer.

Example 14. A semiconductor die, comprising: a semiconductor substrate; a first lateral transistor device and a second lateral transistor device both formed in the semiconductor substrate and both comprising: a channel region; a gate electrode above the channel region and separated from a first main surface of the semiconductor substrate by a gate oxide; and a field oxide formed on the first main surface of the semiconductor substrate and onto which an extension of the gate electrode extends, wherein for the first lateral transistor device, the field oxide comprises a thickness transition region adjoining the gate oxide and having a taper of less than 45 degrees relative to the first main surface of the semiconductor substrate, wherein for the second lateral transistor device, the field oxide comprises a thickness transition region adjoining the gate oxide and having a taper of approximately 45 degrees relative to the first main surface of the semiconductor substrate.

Example 15. The semiconductor die of example 1143, wherein the first lateral transistor device has a lower Rds(on)*A compared to the second lateral transistor device, where Rds(on) is on resistance and A is die area for the transistor device.

Example 16. The semiconductor die of example 14 or 15, wherein the first lateral transistor device has a higher breakdown voltage compared to the second lateral transistor device.

Example 17. The semiconductor die of any of examples 14 through 16, wherein for the first lateral transistor device, the taper is in a range of 5° to 15°.

Example 18. The semiconductor die of any of examples 14 through 17, wherein for both the first lateral transistor device and the second lateral transistor device, the field oxide has a thickness in a range of 20 nm to 400 nm below the extension of the gate electrode outside the thickness transition region.

Example 19. A semiconductor die, comprising: a semiconductor substrate; a source region of a first conductivity type formed in a first main surface of the semiconductor substrate; a drift region of the first conductivity type formed in the first main surface of the semiconductor substrate; a channel region of a second conductivity type opposite the first conductivity type formed in the first main surface of the semiconductor substrate and separating the source region and the drift region; a drain region of the first conductivity type formed in the first main surface of the semiconductor substrate and separated from the channel region by the drift region; a gate electrode above the channel region and separated from the first main surface of the semiconductor substrate by a gate oxide; and a field oxide formed on the first main surface of the semiconductor substrate and onto which an extension of the gate electrode extends, wherein the field oxide comprises a thickness transition region adjoining the gate oxide and having a taper of less than 45 degrees relative to the first main surface of the semiconductor substrate, wherein the extension of the gate electrode extends onto the thickness transition region of the field oxide with the same taper as the thickness transition region.

Example 20. The semiconductor die of example 19, wherein the taper is in a range of 5° to 15°.

Example 21. The semiconductor die of example 19 or 20, wherein the field oxide has a thickness in a range of 20 nm to 400 nm below the extension of the gate electrode outside the thickness transition region.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method, comprising:
forming a first oxide layer on a first main surface of a semiconductor wafer, the first oxide layer having a thickness of 400 nm or less;
forming a second layer on the first oxide layer;
altering an etch rate of at least a first part of the second layer such that a horizontal component (r1) of the etch rate is greater than a vertical component (r2) of an etch rate of the first oxide layer;
etching the second layer and the first oxide layer through an opening in a mask using an isotropic etchant, wherein due to the difference between r1 and r2, a first thickness transition region of the first oxide layer under the mask is etched with a taper of less than 45 degrees relative to the first main surface of the semiconductor wafer;
after the etching, removing the second layer; and
after removing the second layer, forming a gate oxide adjacent to the first thickness transition region.

2. The method of claim 1, wherein r1/r2 is in a range of 3 to 4.

3. The method of claim 1, wherein the taper is in a range of 5° to 15°.

4. The method of claim 1, wherein altering the etch rate of at least the first part of the second layer comprises:
implanting an atomic species into at least the first part of the second layer at an energy and a dose that limit the atomic species to the second layer.

5. The method of claim 4, wherein the atomic species is arsenic.

6. The method of claim 5, wherein the energy is in a range of 1 to 10 keV, and wherein the dose is in a range of 1E13 to 1E16 atoms/cm².

7. The method of claim 4, further comprising:
before both the altering and the etching, adjusting the etch rate of the second layer such that the etch rate of the second layer is closer to or matches the etch rate of the first oxide layer,
wherein during the implanting of the atomic species, the mask shields a second part of the second layer laterally adjoining the first part of the second layer such that the atomic species is restricted to the first part of the second layer,
wherein at the start of the etching, the first thickness transition region is covered by the first part of the second layer and a second thickness transition region of the first oxide layer under the mask is covered by the second part of the second layer,
wherein during the etching, the second thickness transition region is etched with a taper of approximately 45 degrees relative to the first main surface of the semiconductor wafer.

8. The method of claim 7, wherein the first thickness transition region is part of a first device type, and wherein the second thickness transition region is part of a second device type.

9. The method of claim 8, further comprising:
singulating the semiconductor wafer into a plurality of semiconductor dies, each of the semiconductor dies including the first device type and the second device type.

10. The method of claim 8, further comprising:
forming a first gate electrode on the gate oxide, the first gate electrode being part of the first device type and having an extension that extends onto the first thickness transition region; and
forming a second gate electrode on the gate oxide, the second gate electrode being part of the second device type and having an extension that extends onto the second thickness transition region,
wherein relative to the first main surface of the semiconductor wafer, the extension of the first gate electrode is sloped at a smaller angle above the first thickness transition region compared to the extension of the second gate electrode above the second thickness transition region.

11. The method of claim 8, wherein the first device type has a lower Rds(on)*A compared to the second device type, where Rds(on) is on resistance and A is die area for the device type.

12. The method of claim 8, wherein the first device type has a higher breakdown voltage compared to the second device type.

13. The method of claim 1, wherein the second layer is an oxide layer.

14. A semiconductor die, comprising:
a semiconductor substrate;
a first lateral transistor device and a second lateral transistor device both formed in the semiconductor substrate and both comprising:
a channel region;
a gate electrode above the channel region and separated from a first main surface of the semiconductor substrate by a gate oxide; and
a field oxide formed on the first main surface of the semiconductor substrate and onto which an extension of the gate electrode extends,
wherein for the first lateral transistor device, the field oxide comprises a thickness transition region adjoining the gate oxide and having a taper of less than 45 degrees relative to the first main surface of the semiconductor substrate,
wherein for the second lateral transistor device, the field oxide comprises a thickness transition region adjoining the gate oxide and having a taper of approximately 45 degrees relative to the first main surface of the semiconductor substrate.

15. The semiconductor die of claim 14, wherein the first lateral transistor device has a lower Rds(on)*A compared to the second lateral transistor device, where Rds(on) is on resistance and A is die area for the transistor device.

16. The semiconductor die of claim 14, wherein the first lateral transistor device has a higher breakdown voltage compared to the second lateral transistor device.

17. The semiconductor die of claim 14, wherein for the first lateral transistor device, the taper is in a range of 5° to 15°.

18. The semiconductor die of claim 14, wherein for both the first lateral transistor device and the second lateral transistor device, the field oxide has a thickness in a range of 20 nm to 400 nm below the extension of the gate electrode outside the thickness transition region.

19. A semiconductor die, comprising:
a semiconductor substrate;
a source region of a first conductivity type formed in a first main surface of the semiconductor substrate;
a drift region of the first conductivity type formed in the first main surface of the semiconductor substrate;
a channel region of a second conductivity type opposite the first conductivity type formed in the first main surface of the semiconductor substrate and separating the source region and the drift region;
a drain region of the first conductivity type formed in the first main surface of the semiconductor substrate and separated from the channel region by the drift region;
a gate electrode above the channel region and separated from the first main surface of the semiconductor substrate by a gate oxide; and
a field oxide formed on the first main surface of the semiconductor substrate and onto which an extension of the gate electrode extends,
wherein the field oxide comprises a thickness transition region adjoining the gate oxide and having a taper of less than 45 degrees relative to the first main surface of the semiconductor substrate,
wherein the extension of the gate electrode extends onto the thickness transition region of the field oxide with the same taper as the thickness transition region.

20. The semiconductor die of claim 19, wherein the taper is in a range of 5° to 15°.

21. The semiconductor die of claim 19, wherein the field oxide has a thickness in a range of 20 nm to 400 nm below the extension of the gate electrode outside the thickness transition region.
